(19) United States
(12) Patent Application Publication
(10) Pub. No.: US 2014/0029181 A1
(43) Pub. Date: Jan. 30, 2014

(54) INTERLAYER INTERCONNECTS AND ASSOCIATED TECHNIQUES AND CONFIGURATIONS

(71) Applicants: Florian Gstrein, Portland, OR (US); Hui Jae Yoo, Hillsboro, OR (US); Jacob M. Faber, Hillsboro, OR (US); James S. Clarke, Portland, OR (US)

(72) Inventors: Florian Gstrein, Portland, OR (US); Hui Jae Yoo, Hillsboro, OR (US); Jacob M. Faber, Hillsboro, OR (US); James S. Clarke, Portland, OR (US)

(21) Appl. No.: 13/560,930

(22) Filed: Jul. 27, 2012

(51) Int. Cl. H01L 23/522; G06F 1/16; H01L 21/768

(52) U.S. Cl. 361/679.02; 257/762; 438/637; 257/E23.145; 257/E21.585

(57) ABSTRACT

Embodiments of the present disclosure are directed towards interlayer interconnects and associated techniques and configurations. In one embodiment, an apparatus includes a semiconductor substrate, one or more device layers disposed on the semiconductor substrate, and one or more interconnect layers disposed on the one or more device layers, the one or more interconnect layers including interconnect structures configured to route electrical signals to or from the one or more device layers, the interconnect structures comprising copper (Cu) and germanium (Ge). Other embodiments may be described and/or claimed.

### FIELD

Embodiments of the present disclosure generally relate to the field of integrated circuits, and more particularly, to interlayer interconnects and associated techniques and configurations.

### BACKGROUND

Integrated circuit (IC) devices including, for example, logic and/or memory devices continue to scale to smaller sizes. As copper (Cu) based interconnects continue to scale to smaller sizes, current densities may increase and a margin for electromigration (EM) of the interconnects may decrease. Such effect may be particularly seen for metal layers having local interconnects (e.g., Metal 1 through Metal 3 layers) where interconnects are shorter and where line resistance may be dominated by device resistance.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 schematically illustrates a top view of an integrated circuit (IC) device in die form and wafer form, in accordance with some embodiments.

FIG. 2 schematically illustrates a cross-section side view of an IC device, in accordance with some embodiments.

FIG. 3 schematically illustrates a cross-section side view of interconnect layers of an IC device, in accordance with some embodiments.

FIG. 4 schematically illustrates another cross-section side view of interconnect layers of an IC device, in accordance with some embodiments.

FIG. 5 schematically illustrates yet another cross-section side view of interconnect layers of an IC device, in accordance with some embodiments.

FIG. 6 is a flow diagram for a method of fabricating and packaging an IC device, in accordance with some embodiments.

FIG. 7 schematically illustrates a computing device in accordance with one implementation of the invention.

### DETAILED DESCRIPTION

Embodiments of the present disclosure describe interlayer interconnects and associated techniques and configurations. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Various operations are described as multiple discrete operations in turn, in a manner that is most helpful in understanding the claimed subject matter. However, the order of description should not be construed as to imply that these operations are necessarily order dependent.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or elements are in direct contact.

In various embodiments, the phrase “a first layer formed, deposited, or otherwise disposed on a second layer,” may mean that the first layer is formed, deposited, or disposed over the second layer, and at least a part of the first layer may be in direct contact (e.g., direct physical and/or electrical contact) or indirect contact (e.g., having one or more other layers between the first layer and the second layer) with at least a part of the second layer.

As used herein, the term “module” may refer to, be part of, or include an Application Specific Integrated Circuit (ASIC), an electronic circuit, a processor (shared, dedicated, or group) and/or memory (shared, dedicated, or group) that execute one or more software or firmware programs, a combinational logic circuit, and/or other suitable components that provide the described functionality.

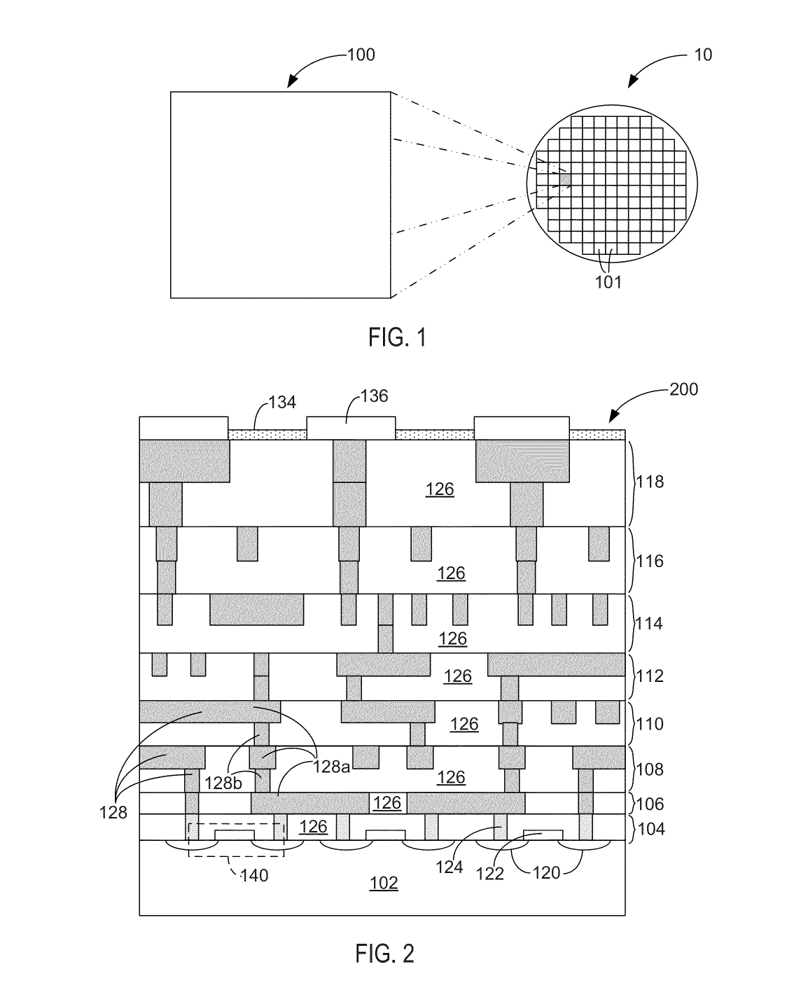

FIG. 1 schematically illustrates a top view of an IC device 100 in die form and wafer form, in accordance with some embodiments. In some embodiments, the IC device 100 may be one of a plurality of IC devices formed on a wafer 10 composed of semiconductor material. The wafer 10 may include one or more dies (hereinafter “dies 101”) formed on a surface of the wafer 10. Each of the dies 101 may be a repeating unit of a semiconductor product that includes the IC device 100. After a fabrication process of the semiconductor product is complete, the wafer 10 may undergo a singulation process in which each of the dies 101 is separated from one another to provide discrete “chips” of the semiconductor product. The wafer 10 may include a variety of sizes. In some embodiments, the wafer 10 has a diameter ranging from about 25.4 mm to about 450 mm. The wafer 10 may include other sizes and/or other shapes in other embodiments.

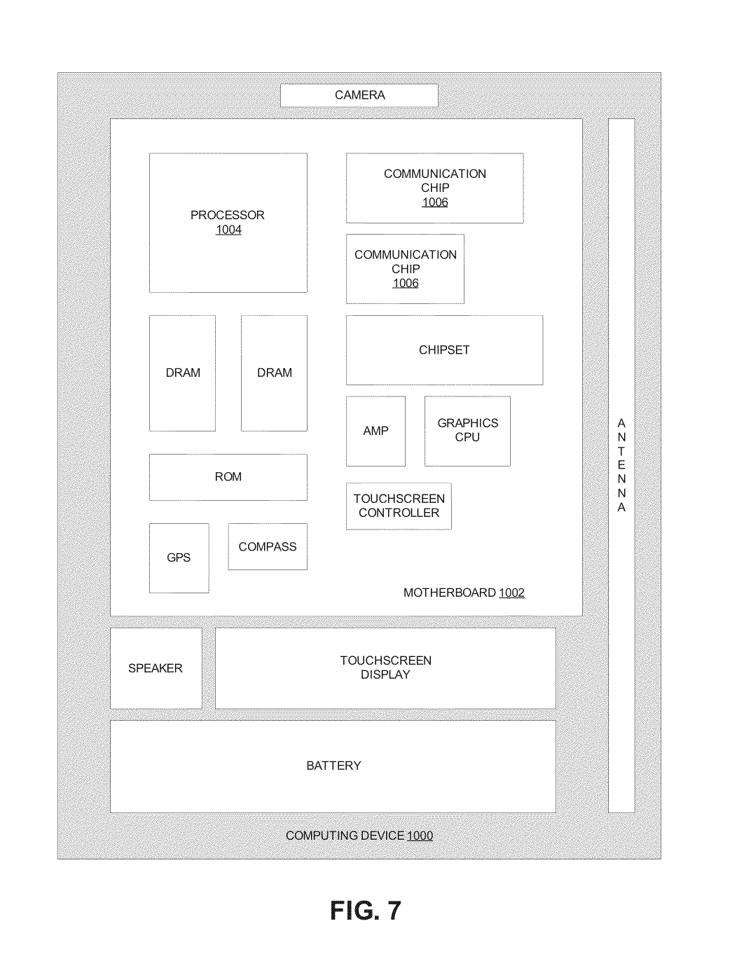

According to various embodiments, the IC device 100 may be in wafer 10 form (e.g., not singulated) or die form (e.g., singulated). In some embodiments, the IC device 100 may correspond with or be part of one of the dies 101. In FIG. 1, one of the dies 101 (shaded in wafer 10) including the IC device 100 is depicted in an exploded view. The IC device 100 may include one or more transistors (e.g., transistors 140 of FIG. 2). In some embodiments, the IC device 100 can include memory and/or logic devices combined on a single die. For example, a memory device may be formed on a same die 101 as a processor (e.g., processor 1004 of FIG. 7) or other logic that is configured to store information in the memory device or execute instructions of the memory device. For example, the IC device 100 may include a processor and cache formed on the same die in some embodiments. Techniques and configurations described herein may be incorporated in logic or memory, or combinations thereof.

FIG. 2 schematically illustrates a cross-section side view of an IC device 200, in accordance with some embodiments. According to various embodiments, the IC device 200 is formed on a substrate 102 (e.g., wafer 10 of FIG. 1). The substrate 102 may be a semiconductor substrate composed of semiconductor material systems including, for example, N-type or P-type materials systems. The substrate 102 may include, for example, a crystalline substrate formed using a bulk silicon or a silicon-on-insulator substructure. In some embodiments, the semiconductor substrate 102 may be formed using alternate materials, which may or may not be combined with silicon, that include but are not limited to germanium, indium antimonide, lead telluride, indium arsenide, indium phosphide, gallium arsenide, or gallium antimonide. Further materials classified as group II-VI, III-V or group IV materials may also be used to form the substrate 102. Although a few examples of materials from which the substrate 102 may be formed are described here, any material that may serve as a foundation upon which an IC device 200 may be used in accordance with various embodiments. In some embodiments, the substrate 102 is part of a singulated die (e.g., dies 101 of FIG. 1) of a wafer (e.g., wafer 10 of FIG. 1).

In some embodiments, the IC device 200 includes one or more device layers (hereinafter “device layer 104”) disposed on the substrate 102. The device layer 104 may include features and components of one or more transistors (hereinafter “transistor(s) 140”) formed on the substrate 102. The device layer 104 may include, for example, one or more source and/or drain regions (hereinafter “S/D regions”) 120, a gate 122 to control current flow in the transistor(s) 140 between the S/D regions 120, and one or more source and/or drain contacts (hereinafter “S/D contacts 124”) to route electrical signals to/from the S/D regions 120.

The transistor(s) 140 may include additional features not depicted for the sake of clarity such as device isolation regions, gate contacts, and the like. The transistor(s) 140 are not limited to the type and configuration depicted in FIG. 2 and may include a wide variety of other types and configurations such as, for example, planar and non-planar transistors such as dual- or double-gate transistors, tri-gate transistors, and all-around gate (AAG) or wrap-around gate transistors, some of which may be referred to as FinFETs (Field Effect Transistors). In some embodiments, the device layer 104 includes one or more transistors or memory cells of a logic device or a memory device, or combinations thereof.

Electrical signals such as, for example, power and/or input/output (I/O) signals may be routed to and/or from the transistor(s) 140 of the device layer 104 through one or more interconnect layers (e.g., hereinafter “interconnect layers 106-118”) disposed on the device layer 104. For example, electrically conductive features of the device layer 104 such as, for example, the gate 122 and S/D contacts 124 may be electrically coupled with interconnect structures 128 of the interconnect layers 106-118. The interconnect structures 128 may be configured within the interconnect layers 106-118 to route electrical signals according to a wide variety of designs and is not limited to the particular configuration of interconnect structures 128 depicted in the figures. Although a particular number of interconnect layers 106-118 is depicted for the configuration in FIG. 2, embodiments of the present disclosure include IC devices having more or fewer interconnect layers 106-118 than depicted.

In some embodiments, the interconnect structures 128 may include trench structures 128a (sometimes referred to as “lines”) and/or via structures 128b (sometimes referred to as “holes”) filled with an electrically conductive material such as, for example, copper germanide (Cu₃Ge). The interconnect structures 128 may be interlayer interconnects that provide routing of electrical signals through a stack of interconnect layers 106-118.

In some embodiments, the trench structures 128a may be configured to route electrical signals in a direction of a plane that is substantially parallel with a surface of the substrate 102 upon which the device layer 104 is formed. For example, the trench structures 128a may route electrical signals in a direction in and out of the page in the perspective of FIG. 2, in some embodiments. The via structures 128b may be configured to route electrical signals in a direction of a plane that is substantially perpendicular with the surface of the substrate 102 upon which the device layer 104 is formed. In some embodiments, the via structures 128b may electrically couple trench structures 128a of different interconnect layers 106-118 together. In various embodiments, a succession of interconnect layers 106-118 may be stacked on the device layer 104 to route electrical signals to or from the device layer 104.

The interconnect layers 106-118 may include a dielectric material 126 disposed between the interconnect structures 128, as can be seen. The dielectric material may be composed of a variety of suitable materials including, for example, carbon-doped silicon oxide (SiOC) or fluorine-doped silicon oxide (SiOF).

According to various embodiments, a first interconnect layer 106 (referred to as Metal 1 or “M1”) may be formed directly on the device layer 104. In some embodiments, the first interconnect layer 106 may include trench structures 128a, as can be seen. The trench structures 128a of the first interconnect layer 106 may be coupled with contacts (e.g., S/D contacts 124) of the device layer 104.

A second interconnect layer 108 (referred to as Metal 2 or “M2”) may be formed directly on the first interconnect layer 106. In some embodiments, the second interconnect layer 108 may include via structures 128b to couple trench structures 128a of the second interconnect layer 108 with trench structures 128a of the first interconnect layer 106. Although the trench structures 128a and the via structures 128b are structurally delineated with a line within each interconnect layer (e.g., within the second interconnect layer 108) for the sake of clarity, the trench structures 128a and the via structures 128b may be structurally and/or materially contiguous (e.g., simultaneously filled during a dual-damascene process) in some embodiments.

A third interconnect layer 110 (referred to as Metal 3 or “M3”), fourth interconnect layer 112 (referred to as Metal 4 or “M4”), fifth interconnect layer 114 (referred to as Metal 5 or “M5”), sixth interconnect layer 116 (referred to as Metal 6 or “M6”), and seventh interconnect layer 118 (referred to as Metal 7 or “M7”) may be formed in succession on the second interconnect layer 108 according to similar techniques and configurations described in connection with the second interconnect layer 108 on the first interconnect layer 106.

According to various embodiments, one or more of the interconnect structures 128 of the interconnect layers 106-118 may be primarily composed of a material having any suitable stoichiometric ratio of copper (Cu) and Germanium (Ge). The Cu and Ge may be in the form of a chemical compound. In one embodiment, the interconnect structures 128 may comprise copper germanide (Cu₃Ge). The use of Cu in conjunction with Ge (e.g., Cu₃Ge) as an interconnect material of the interconnect structures 128 may provide a variety of benefits. For example, copper germanide material may provide superior resistance to electromigration relative to copper, provide lower line-to-line resistance or lower via resistivity relative to copper, and/or reduce fabrication costs by allowing or facilitating the elimination of various process operations and/or materials (e.g., fabrication of barrier liner and/or hermetic dielectric).

In some embodiments, the interconnect structures 128 may be primarily or entirely composed of copper germanide (Cu₃Ge). For example, in some embodiments, the Cu₃Ge may provide a bulk portion of the interconnect structures 128. In some embodiments, the Cu₃Ge may be used in conjunction with a barrier liner. For example, a barrier liner (e.g., barrier liner 430 of FIG. 4) composed of materials such as, for example, tantalum (Ta), tantalum nitride (TaN), ruthenium (Ru), or combination thereof, may be disposed between the interconnect structures 128 and dielectric material 126 in some embodiments.

In other embodiments, a copper germanide based interconnect material may allow or otherwise facilitate elimination of a barrier liner (e.g., barrier liner 430 of FIG. 4) that may be used in conventional practice to provide an electromigration barrier between copper of the interconnect structures 128 and the dielectric material 126. For example, the Cu₃Ge may be in direct contact with the dielectric material 126 in some embodiments. In such embodiments, the interconnect structures 128 may be composed primarily of Cu₃Ge and may include other stoichiometric alloys of Cu and Ge or Cu and Ge nanoclusters. Copper germanide may have a lower resistivity than a resistivity of traditional barrier liner materials such as, for example, tantalum nitride (TaN) and the like. In addition to cost savings associated with eliminating materials and process steps in forming the barrier liner, the elimination of barrier liner materials may further facilitate scaling of line resistance in the IC device 200.

The copper-germanide based interconnect material may further allow or facilitate elimination of a hermetic dielectric layer (e.g., hermetic dielectric layer 432 of FIG. 4). The hermetic dielectric layer may be a high-k dielectric that may be used in conventional practice to provide an oxidation/corrosion barrier between each interconnect layer of the interconnect layers 106-118. Copper germanide may resist oxidation and/or other corrosion (e.g., silicide formation) relative to copper allowing elimination of the hermetic dielectric layer between adjacent interconnect layers of the interconnect layers 106-118. In addition to cost savings associated with eliminating materials and process steps in forming the hermetic dielectric layer, elimination of the hermetic dielectric layer may provide layer-to-layer (e.g., adjacent interconnect layers of the interconnect layers 106-118) capacitance savings of 10% or more.

In some embodiments, Cu and Ge of the interconnect structures 128 may be in direct contact with the dielectric material 126. No intervening material may be present between Cu and Ge of the interconnect structures 128 and the dielectric material 126 in some embodiments. Cu and Ge of individual interconnect structures of the interconnect structures 128 may be in direct contact with Cu and Ge of other individual interconnect structures of the interconnect structures 128, in some embodiments. In some embodiments, Cu and Ge of the trench structures 128a of an interconnect layer may be in direct contact with Cu and Ge of via structures 128b of the same interconnect layer. In other embodiments, Cu and Ge of an interconnect layer may be in direct contact with Cu and Ge of another interconnect layer. For example, in some embodiments, the Cu and Ge of the via structures 128b disposed in the second interconnect layer 108 may be in direct contact with Cu and Ge of the trench structures 128a disposed in the first interconnect layer 106, Cu and Ge of the via structures 128b disposed in the third interconnect layer 110 may be in direct contact with Cu and Ge of the trench structures 128 disposed in the second interconnect layer 108, and so forth.

In other embodiments, an individual interconnect structure of the interconnect structures 128 may include an intervening material such as, for example, a barrier liner material disposed between Cu and Ge of the individual interconnect structure (e.g., trench structure of trench structures 128a) and Cu and Ge of an adjacent interconnect structure (e.g., via structure of via structures 128b) that is directly coupled with the individual interconnect structure. In some embodiments, improved electromigration capacitance savings can be realized for the IC device 100 even where a barrier liner material is disposed between Cu and Ge of the individual interconnect structure and Cu and Ge of the adjacent interconnect structure relative to an IC device 100 that uses Cu only in conjunction with a barrier liner. For example, in some embodiments, the Cu and Ge of the first interconnect layer 106 may be directly coupled with a barrier liner material of the second interconnect layer 108. The barrier liner material may be composed of a metal other than Cu in some embodiments. Similar principles may apply to other interconnect layers of the interconnect layers 106-118.

In some embodiments, the dielectric material 126 of one interconnect layer (e.g., first interconnect layer 106) may be in direct contact with dielectric material 126 of another interconnect layer (e.g., second interconnect layer 108). The dielectric material 126 may have the same chemical composition. That is, in some embodiments, no intervening hermetic dielectric layer (e.g., silicon nitride or silicon carbide) may be disposed between the dielectric material 126 (e.g., SiOC or SiOF) of adjacent interconnect layers. In some embodiments, the dielectric material 126 may include an air gap (not shown) in the dielectric material 126. The air gap may be disposed, for example, between solid material of the dielectric material 126 and materials of the interconnect structures 128. Oxidation of Cu₃Ge may make the Cu₃Ge material a good candidate material for use in conjunction with an air gap in the dielectric material

In some embodiments, features of the device layer 104 may comport with embodiments described herein. For example, contacts in the device layer 104 such as, for example, S/D contacts 124 may be composed of Cu and Ge (e.g., Cu₃Ge) in some embodiments. The dielectric material 126 disposed in the device layer 104 may be in direct contact with Cu and Ge of the contacts and in direct contact with the dielectric material 126 disposed in the first interconnect layer 106. The Cu and Ge of the S/D contacts 124 may be in direct contact with Cu and Ge of the interconnect structures 128 of the first interconnect layer 106. The same principle may be applied to gate contacts (not shown) of the device layer 104. In some embodiments, one or more of the interconnect layers 106-118 may include interconnect structures 128 composed of Cu and Ge.

The IC device 200 may include a passivation layer 134 (e.g., polyimide or similar material) and one or more bond pads 136 formed on the interconnect layers 106-118. The bond pads 136 may be electrically coupled with the interconnect structures 128 and configured to route the electrical signals of transistor(s) 140 to other external devices. For example, solder bonds may be formed on the one or more bond pads 136 to mechanically and/or electrically couple a chip including the IC device 200 with another component such as a circuit board. The IC device 200 may have other alternative configurations to route the electrical signals from the interconnect layers 106-118 than depicted in other embodiments. In other embodiments, the bond pads 136 may be replaced by or may further include other analogous features (e.g., posts) that route the electrical signals to other external components.

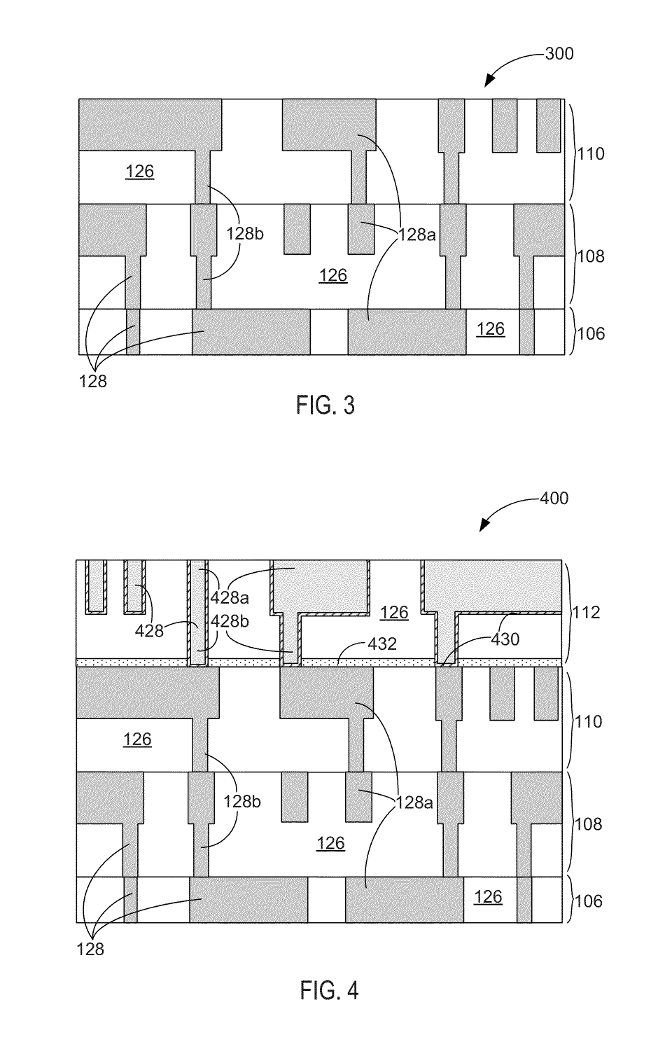

FIG. 3 schematically illustrates a cross-section side view of interconnect layers 106-110 of an IC device 300, in accordance with some embodiments. The interconnect layers 106-110 may comport with embodiments described in connection with FIG. 2. In some embodiments, inner interconnect layers 106-110 that are disposed adjacent to the device layer (e.g., device layer 104 of FIG. 2) may include smaller interconnect structures 128 that may be more susceptible to increasing current densities and decreasing electromigration resistance associated with continued scaling of IC devices to smaller sizes.

Embodiments described herein may be particularly advantageous for the inner interconnect layers 106-110, which may have a line resistance that is dominated by device resistance. In some embodiments, the first interconnect layer 106, the second interconnect layer 108, and the third interconnect layer 110 include interconnect structures 128 composed of copper germanide. The copper germanide of interconnect layer 108 may be in direct contact with copper germanide of interconnect layers 106, 110. The dielectric material 126 of interconnect layer 108 may be in direct contact with dielectric material 126 of interconnect layers 106, 110. The copper germanide of interconnect layers 106-110 may be in direct contact with surrounding dielectric material 126.

FIG. 4 schematically illustrates another cross-section side view of interconnect layers 106-112 of an IC device 400, in accordance with some embodiments. In some embodiments, techniques and configurations described in connection with interconnect structures 128 composed of Cu and Ge (e.g., Cu₃Ge) may be combined with interconnect structures 428 composed of Cu only (e.g., no Ge) and having a barrier liner 430. The interconnect structures 428 may include, for example, trench structures 428a and via structures 428b.

For example, in the depicted embodiment, the interconnect layers 106-110 may be composed of copper germanide in accordance with the description in connection with FIG. 3. A fourth interconnect layer 112 may include interconnect structures 428 which may be Cu-only based interconnect structures. A barrier liner 430 may be disposed between Cu of the interconnect structures 428 and dielectric material 126 of the fourth interconnect layer 112 and further between Cu of the interconnect structures 428 and Cu and Ge of the interconnect structures 128 disposed in the third interconnect layer 110, as can be seen. In some embodiments, the barrier liner 430 may be composed of a material other than Cu such as, for example, tantalum (Ta), titanium (Ti), or tungsten (W). In some embodiments, the barrier liner 430 may include tantalum nitride (TaN).

The fourth interconnect layer 112 may include a hermetic dielectric layer 432 that is configured to prevent oxidation or other corrosion of features in the underlying layers. The hermetic dielectric layer 432 may be disposed between dielectric material 126 that forms a dielectric layer of the fourth interconnect layer 112 and dielectric material 126 that forms a dielectric layer of the third interconnect layer 110. The hermetic dielectric layer 432 may have a different chemical composition than the dielectric material 126. In some embodiments, the hermetic dielectric layer 432 may be composed of silicon nitride (SiN) or silicon carbide (SiC). The hermetic dielectric layer 432 may have a thickness that is smaller than a thickness of the dielectric material 126. Other interconnect layers similarly configured as the fourth interconnect layer 112 of FIG. 4 may be stacked on the fourth interconnect layer 112 in various embodiments.

In other embodiments, more or fewer interconnect layers may be composed of copper germanide than depicted. For example, in other embodiments, only the interconnect structures 128 of the first interconnect layer 106 may be composed of copper germanide while the second interconnect layer 108 and any other succeeding interconnect layers (e.g., third interconnect layer 110 and so forth) may include interconnect structures composed of copper-only interconnects (e.g., interconnect structures 428) having an intervening barrier liner (e.g., barrier liner 430) and/or intervening hermetic dielectric layer (e.g., hermetic dielectric layer 432). In still other embodiments, only the interconnect structures 128 of the first interconnect layer 106 and the second interconnect layer 108 may be composed of copper germanide while the third interconnect layer 110 and any succeeding interconnect layers may be composed of copper-only interconnects having an intervening barrier liner and/or intervening hermetic dielectric layer, and so forth.

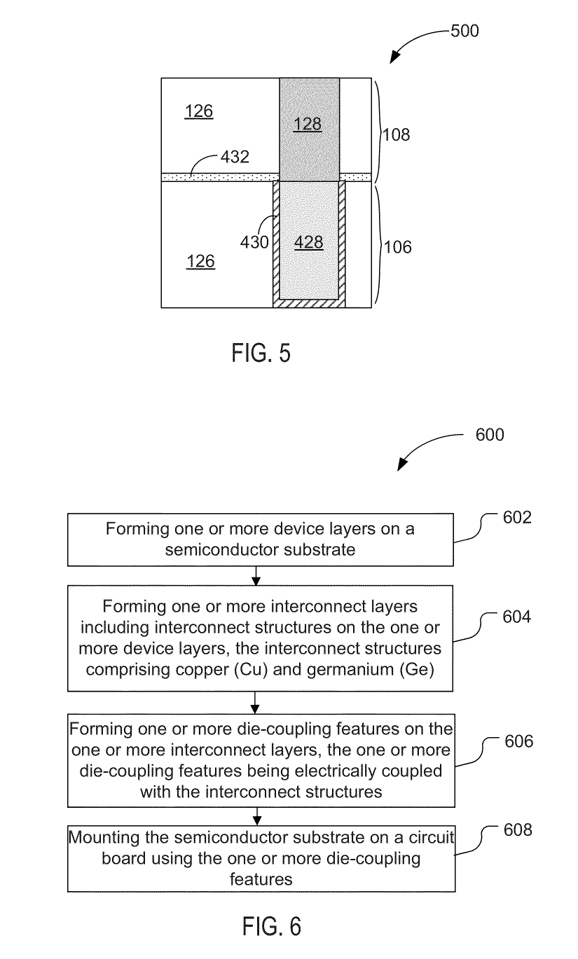

FIG. 5 schematically illustrates yet another cross-section side view of interconnect layers 106, 108 of an IC device 500, in accordance with some embodiments. In some embodiments, an interconnect layer (e.g., second interconnect layer 108) having an interconnect structure 128 composed of copper germanide may be formed on an interconnect layer (e.g., first interconnect layer 106) having an interconnect structure 428 composed of only copper (e.g., no Ge). In the depicted configuration, Cu and Ge of the interconnect structure 128 may be in direct contact with Cu of the interconnect structure 428 and further in direct contact with dielectric material 126 of the second interconnect layer 108.

A hermetic dielectric layer 432 may be disposed between dielectric material 126 of the adjacent interconnect layers (e.g., interconnect layers 106, 108). A barrier liner 430 may be disposed between Cu of the interconnect structure 428 and dielectric material 126 of the first interconnect layer 106. The interconnect layers 106 and 108 are merely representative examples and other interconnect layers (e.g., any of interconnect layers 106-118) or the device layer 104 of FIG. 2 may comport with embodiments of the described configuration of FIG. 5 in other embodiments. For example, in some embodiments, the interconnect structure 428 of FIG. 5 may represent a contact (e.g., S/D contacts 124 of FIG. 2) of the device layer (e.g., device layer 104 of FIG. 2) and the interconnect structure 128 may represent an interconnect structure of a first interconnect layer (e.g., first interconnect layer 106 of FIG. 2).

FIG. 6 is a flow diagram for a method 600 of fabricating and packaging an IC device (e.g., the IC device 200 of FIG. 2), in accordance with some embodiments. The method 600 may comport with embodiments described in connection with FIGS. 1-5.

At 602, the method 600 includes forming one or more device layers (e.g., device layer 104 of FIG. 2) on a semiconductor substrate (e.g., substrate 102 of FIG. 2). The one or more device layers may be formed using semiconductor fabrication processes such as deposition and patterning (e.g., etch and/or lithography) of various materials to form one or more transistors (e.g., transistor(s) 140 of FIG. 2) or memory cells of the IC device. The IC device may include, for example, a logic device, a memory device, or combinations thereof.

At 604, the method 600 may further include forming one or more interconnect layers (e.g., interconnect layers 106-118 of FIG. 2) including interconnect structures (e.g., interconnect structures 128 of FIG. 2) on the one or more device layers, the interconnect structures comprising Cu and Ge. In some embodiments, the interconnect structures comprise copper germanide (Cu₃Ge).

The one or more interconnect layers may be formed by depositing a dielectric material (e.g., dielectric material 126 of FIG. 2) on the one or more device layers and selectively removing portions of the dielectric material to form trench openings and/or via openings in the dielectric layer. In some embodiments, the dielectric material may be selectively removed by a patterning process including etch and lithography processes. Cu and Ge may be deposited into the trench openings and/or via openings to form the interconnect structures such that the Cu and Ge are in direct contact with the dielectric material. In some embodiments, a dual-damascene process may be used to simultaneously form the interconnect structures (e.g., trench structures and via structures) of an individual interconnect layer of the interconnect layers.

In some embodiments, the Cu and Ge is deposited by depositing Cu in the trench openings and/or the via openings and exposing the deposited Cu to germane (GeH₄) to form copper germanide (Cu₃Ge). The Cu may be deposited according to a variety of techniques including, for example, depositing a Cu seed layer into the trench openings and/or the via openings using a chemical vapor deposition (CVD) process followed by electroplating Cu onto the Cu seed layer, a bottom-up fill process using CVD, Cu reflow on the dielectric, Cu reflow on a sacrificial liner, and the like. In some embodiments, the Cu and germane may be iteratively deposited in thin film layers to reduce effects of volumetric expansion of the materials. In other embodiments, germane and copper may be simultaneously deposited.

In some embodiments, a chemical mechanical polishing (CMP) process may be performed prior to exposing the deposited Cu to germane in order to remove deposited Cu to provide gap fill and/or mitigate overburden formation in the trench openings and/or via openings. For example, in embodiments where an electroplating process is used, CMP may recess the Cu to allow formation of the Cu₃Ge by introducing GeH₄ to the recessed area. In some embodiments, the GeH₄ may be introduced to the deposited Cu at temperatures less than 400° C. and at pressures ranging from about 5 milliTorr (mTorr) to 50 mTorr.

Successive interconnect layers may be formed on the interconnect layer already described by depositing a dielectric material having the same chemical composition as the dielectric material of the formed interconnect layer directly on the deposited dielectric material and repeating the actions described above.

At 606, the method 600 may further include forming one or more die-coupling features (e.g., bond pads 136 of FIG. 2) on the one or more interconnect layers, the one or more die-coupling features being electrically coupled with the interconnect structures. The one or more die-coupling features may be formed by depositing and patterning an electrically conductive material such as metal.

At 608, the method 600 may further include mounting the semiconductor substrate on a circuit board (e.g., motherboard 1002 of FIG. 7) using the one or more die-coupling features. In some embodiments, the semiconductor substrate may be flip-chip mounted on the circuit board or mounted using any suitable surface mount technology (SMT).

Embodiments of the present disclosure may be implemented into a system using any suitable hardware and/or software to configure as desired. FIG. 7 schematically illustrates a computing device 1000 in accordance with one implementation of the invention. The computing device 1000 houses a board such as motherboard 1002. The motherboard 1002 may include a number of components, including but not limited to a processor 1004 and at least one communication chip 1006. The processor 1004 is physically and electrically coupled to the motherboard 1002. In some implementations the at least one communication chip 1006 is also physically and electrically coupled to the motherboard 1002. In further implementations, the communication chip 1006 is part of the processor 1004.

Depending on its applications, computing device 1000 may include other components that may or may not be physically and electrically coupled to the motherboard 1002. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1006 enables wireless communications for the transfer of data to and from the computing device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing device 1000 includes an integrated circuit die packaged within the processor 1004. In some implementations of the invention, the integrated circuit die (e.g., dies 101 of FIG. 1) of the processor 1004 includes an IC device (e.g., IC device 200 of FIG. 2), as described herein. The term “processor” may refer to any device or portion of a device that processes electronic data from registers and/or memory to transform that electronic data into other electronic data that may be stored in registers and/or memory.

The communication chip 1006 also includes an integrated circuit die packaged within the communication chip 1006. In accordance with another implementation of the invention, the integrated circuit die of the communication chip includes an IC device (e.g., IC device 200 of FIG. 2), as described herein.

In further implementations, another component (e.g., memory device or other integrated circuit device) housed within the computing device 1000 may contain an integrated circuit die that includes an IC device (e.g., IC device 200 of FIG. 2), as described herein.

In various implementations, the computing device 1000 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 1000 may be any other electronic device that processes data.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. An apparatus comprising:
a semiconductor substrate;
a device layer disposed on the semiconductor substrate; and
one or more interconnect layers disposed on the device layer, the one or more interconnect layers including interconnect structures configured to route electrical signals to or from the device layer, the interconnect structures comprising copper (Cu) and germanium (Ge).

2. The apparatus of claim 1, wherein the interconnect structures comprise copper germanide (Cu₃Ge).

3. The apparatus of claim 1, wherein the interconnect structures include trench structures and via structures.

4. The apparatus of claim 3, wherein the one or more interconnect layers comprise:
a first interconnect layer of trench structures and/or via structures, the first interconnect layer being directly coupled with the device layer;
a second interconnect layer of trench structures and/or via structures, the second interconnect layer being directly coupled with the first interconnect layer; and
a third interconnect layer of trench structures and/or via structures, the third interconnect layer being directly coupled with the second interconnect layer.

5. The apparatus of claim 4, wherein:
the Cu and Ge of the first interconnect layer is directly coupled with the Cu and Ge of the second interconnect layer.

6. The apparatus of claim 4, wherein:
the Cu and Ge of the first interconnect layer is directly coupled with a barrier liner material of the second interconnect layer, the barrier liner material comprising a metal other than Cu.

7. The apparatus of claim 4, wherein:
the first interconnect layer further comprises a first dielectric layer composed of a first dielectric material;
the second interconnect layer further comprises a second dielectric layer composed of a second dielectric material;
the third interconnect layer further comprises a third dielectric layer composed of a third dielectric material;
the first dielectric material, the second dielectric material, and the third dielectric material have a same chemical composition; and
at least one of the first dielectric material and the second dielectric material or the second dielectric material and the third dielectric material are in direct contact.

8. The apparatus of claim 7, wherein the first dielectric material, the second dielectric material and the third dielectric material comprise carbon-doped silicon oxide (SiOC) or fluorine-doped silicon oxide (SiOF).

9. The apparatus of claim 1, wherein:
the one or more interconnect layers further comprise a dielectric material disposed between the interconnect structures; and
the Cu and Ge is directly coupled with the dielectric material.

10. The apparatus of claim 1, further comprising:
another interconnect layer disposed on the one or more interconnect layers, the another interconnect layer comprising other interconnect structures comprising Cu and no Ge, a dielectric material disposed between the other interconnect structures, and a barrier liner comprising a metal other than Cu disposed between the Cu of the other interconnect structures and the dielectric material of the another interconnect layer.

11. The apparatus of claim 10, wherein the barrier liner comprises tantalum (Ta), titanium (Ti), or tungsten (W).

12. The apparatus of claim 10, wherein:
the dielectric material is a first dielectric material of a first dielectric layer;
the another interconnect layer further includes a second dielectric layer comprising a second dielectric material;
the second dielectric layer is disposed between the first dielectric layer and the one or more interconnect layers; and
the first dielectric material has a different chemical composition than the second dielectric material.

13. The apparatus of claim 12, wherein:
the second dielectric material comprises silicon nitride (SiN) or silicon carbide (SiC); and
the second dielectric layer has a thickness that is smaller than a thickness of the first dielectric layer.

14. The apparatus of claim 1, wherein the device layer comprises:
one or more transistors or memory cells of a logic device or memory device.

15. A method comprising:
forming a device layer on a semiconductor substrate; and
forming one or more interconnect layers disposed on the device layer, the one or more interconnect layers including interconnect structures configured to route electrical signals to or from the device layer, the interconnect structures comprising copper (Cu) and germanium (Ge).

16. The method of claim 15, wherein forming the device layer comprises:
forming one or more transistors or memory cells of a logic device or memory device.

17. The method of claim 15, wherein forming the one or more interconnect layers comprises:
depositing a dielectric material to form a dielectric layer on the device layer;
selectively removing portions of the dielectric material to form trench openings and/or via openings in the dielectric layer; and
depositing Cu and Ge to form the interconnect structures in the trench openings and/or the via openings, the Cu and Ge being in direct contact with the dielectric material.

18. The method of claim 17, wherein selectively removing portions of the dielectric material and depositing Cu and Ge are performed using a dual-damascene process.

19. The method of claim 17, wherein depositing Cu and Ge comprises:
depositing Cu in the trench openings and/or the via openings; and
exposing the deposited Cu to germane (GeH₄) to form copper germanide (Cu₃Ge).

20. The method of claim 19, wherein the Cu is deposited using an electroplating process, the method further comprising:
performing a chemical-mechanical polishing (CMP) process on the deposited Cu prior to exposing the deposited Cu to the germane.

21. The method of claim 17, wherein depositing the dielectric material, selectively removing portions of the dielectric material, and depositing Cu and Ge are part of a process to fabricate a first interconnect layer of the one or more interconnect layers, the first interconnect layer being directly coupled with the device layer, and wherein the dielectric material is a first dielectric material, the dielectric layer is a first dielectric layer, and the interconnect structures are first interconnect structures, the method further comprising:
forming a second interconnect layer by
depositing a second dielectric material to form a second dielectric layer on the first interconnect layer;
selectively removing portions of the second dielectric material to form trench openings and/or via openings in the second dielectric layer; and
depositing Cu and Ge to form second interconnect structures in the trench openings and/or via openings formed in the second dielectric layer, wherein the Cu and Ge of the second interconnect structures are in direct contact with the second dielectric material and the Cu and Ge of the first interconnect structures.

22. The method of claim 21, wherein depositing the second dielectric material comprises:
depositing the second dielectric material on the first dielectric material, the second dielectric material being in direct contact with the first dielectric material and the first dielectric material and the second dielectric material having a same chemical composition.

23. A computing device comprising:
a motherboard;
a communication chip mounted on the motherboard; and
a processor or a memory device mounted on the motherboard, the communication chip, the processor, or the memory device comprising:
a semiconductor substrate;
a device layer disposed on the semiconductor substrate; and
one or more interconnect layers disposed on the device layer, the one or more interconnect layers including interconnect structures configured to route electrical signals to or from the device layer, the interconnect structures comprising copper (Cu) and germanium (Ge).

24. The computing device of claim 23, wherein the interconnect structures comprise copper germanide (Cu₃Ge).

25. The computing device of claim 23, wherein the one or more interconnect layers comprise:
a first interconnect layer of trench structures and/or via structures, the first interconnect layer being directly coupled with the device layer;
a second interconnect layer of trench structures and/or via structures, the second interconnect layer being directly coupled with the first interconnect layer; and
a third interconnect layer of trench structures and/or via structures, the third interconnect layer being directly coupled with the second interconnect layer.

26. The computing device of claim 25, wherein:
the Cu and Ge of the first interconnect layer is directly coupled with the Cu and Ge of the second interconnect layer.

27. The computing device of claim 25, wherein:
the first interconnect layer further comprises a first dielectric layer composed of a first dielectric material;
the second interconnect layer further comprises a second dielectric layer composed of a second dielectric material;
the third interconnect layer further comprises a third dielectric layer composed of a third dielectric material;
the first dielectric material, the second dielectric material, and the third dielectric material have a same chemical composition; and
at least one of the first dielectric material and the second dielectric material or the second dielectric material and the third dielectric material are in direct contact.

28. The computing device of claim 23, wherein:
the one or more interconnect layers further comprise a dielectric material disposed between the interconnect structures; and
the Cu and Ge is directly coupled with the dielectric material.

29. The computing device of claim 23, further comprising:
another interconnect layer disposed on the one or more interconnect layers, the another interconnect layer comprising other interconnect structures comprising Cu and no Ge, a dielectric material disposed between the other interconnect structures, and a barrier liner comprising a metal other than Cu disposed between the Cu of the other interconnect structures and the dielectric material of the another interconnect layer.

30. The computing device of claim 23, wherein:
the device layer comprises one or more transistors or memory cells of the processor or the memory device; and
the computing device is a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder.
